(19) United States
(12) Patent Application Publication
(10) Pub. No.: US 2026/0255993 A1
(43) Pub. Date: Aug. 27, 2026

(54) MULTI-CHIP MODULE AND METHOD FOR MANUFACTURING THEREOF

(71) Applicant: INPACK TECHNOLOGIES - LIMITED PARTNERSHIP, Migdal HaEmek (IL)

(72) Inventor: Joseph KAPLUN, Petah Tikva (IL)

(21) Appl. No.: 19/162,948

(22) PCT Filed: Mar. 18, 2024
(86) PCT No.: PCT/IL2024/050283

§ 371 Date: Sep. 7, 2025

Related U.S. Application Data
(60) Provisional application No. 63/453,243, filed on Mar. 20, 2023.

(51) Int. Cl. H10W 70/60; H10W 40/20; H10W 70/06; H10W 70/09; H10W 70/655; H10W 74/01; H10W 74/47; H10W 90/00; H10W 90/10

(52) U.S. Cl. CPC H10W 70/614; H10W 40/233; H10W 40/242; H10W 70/06; H10W 70/09; H10W 90/10; H10W 90/736; H10W 70/655; H10W 74/01; H10W 74/47

(57) ABSTRACT

Disclosed herein is a multi-chip module having an open/exposed/bare backside including a heat sink, the heat sink configured for heat dissipation from the multi-chip module, one or more electronic components, and a front side comprising a coreless interposer including: a plurality of layers, wherein each of the plurality of layers includes a plurality of conducting lines/pads and one or more gaps between the plurality of conducting lines/pads, wherein the one or more gaps are filled with an insulating material, and wherein the one or more electronic components are positioned between the coreless interposer and the heat sink, and wherein the front side is configured for electrical communication with external electrical components.

### TECHNICAL FIELD

The present disclosure relates generally to semiconductor devices, and more particularly to a multi-chip module and methods for manufacturing thereof.

### BACKGROUND

The continuous need and effort to minimize semiconductor devices, reduce the power of consumption and improve their performance are currently facing several challenges. One of the major challenges originates from the use of printed circuit boards (PCBs) and package assemblies of semiconductor dies, chips or integrated circuits mounted thereon. The purpose of the PCB is to connect packaged integrated circuits, passive electronic components, and other components into a working device/system. However, it is difficult to manufacture flat PCBs, since they are prone to warpage. Packaged dies are usually connected to a PCB via a set of solder bumps, which are melted and re-solidified during the manufacturing process. The limitations of soldering technology, combined with surface warpage, lead to placing the solder bumps at least 0.5 millimeters apart. Consequently, requiring large distance between each circuit component, which, in turn, leads to reduced speed of signals transfer, increased power consumption, low resolution (due to the increased distance between the conducting pads on the printed circuit board), and inefficient heat transfer. Put differently, package designs are currently limited by input/output count/density and heat dissipation, which, in turn, limit the speed and increase the power consumption of the device. This bottleneck is of particular importance for data-intensive applications, such as graphics, machine learning, and the like.

Several approaches are developed to overcome these challenges, such as system on a chip (SoC) design, wherein a single large chip integrates different components, such as a central processing unit, graphics and memory interfaces, and the like, instead of mounting each of the components separately. The SoC chips demonstrate short distance between each component, thereby enhancing the performance. However, when SoCs are mounted on PCBs, they inevitably lose their advantages due to limitations of the PCBs. Furthermore, increase in the size and complexity of each of SoC increases the number of defects during the advanced and highly expensive production process, resulting in low yield.

Additional current approach, instead of integrating all or most of the components on a single chip, is to fabricate smaller modules including multiple integrated circuits assembled into a single device-multi-chip modules (MCMs). Traditional MCMs implement an interposer, typically made of a silicon or glass substrate equipped with drilled vertical electrical connections (e.g., through-substrate vias). Attaching components directly on the interposer solves few of the challenges. However, the interposers are required to be equipped with large contact pads to be mounted on a PCB, thereby limiting their resolution and heat dissipation. Furthermore, manufacturing of the through-substrate vias for interconnecting top and bottom contact pads of the interposer (to allow interconnecting between the chips and the PCB) is expensive, especially for interposers with reduced thickness, which are prone to cracking and warping and are limited by line/space resolution.

### SUMMARY

Aspects of the disclosure, according to some embodiments thereof, relate to semiconductor devices. More specifically, but not exclusively, aspects of the disclosure, according to some embodiments thereof, relate to a multi-chip module and methods for manufacturing thereof.

Thus, according to an aspect of some embodiments, there is provided a multi-chip module. According to some embodiments, the multi-chip model comprises an open/exposed/bare backside including a heat sink, a front side including an interposer, and one or more electronic components, wherein the one or more electronic components are positioned between the interposer and the heat sink, and wherein the front side is configured for electrical communication with other/external components or devices.

According to some embodiments, there is provided a multi-chip module including: an open/exposed/bare backside including a heat sink, the heat sink configured for heat dissipation from the multi-chip module, one or more electronic components, and a front side including a coreless interposer, the coreless interposer including a plurality of layers, wherein each of the plurality of layers includes a plurality of conducting lines/pads, and one or more gaps between the plurality of conducting lines/pads, wherein the one or more gaps are filled with an insulating material; and wherein the one or more electronic components are positioned between the coreless interposer and the heat sink; and wherein the front side is configured for electrical communication with external electrical components.

According to some embodiments, the disclosed multi-chip module includes conductive lines interspersed among dielectric layers, and one or more electronic components (such as, but not limited to, bare integrated circuit dies) placed in and connected to the conductive lines. Advantageously, in some embodiments, enabling design and manufacture of compact and light-weight electronic devices (such as, but not limited to, wearable electronic devices). Advantageously, in some embodiments, enabling design and manufacture of high-performance computers, service centres, and the like.

According to some embodiments, the disclosed multi-chip module includes electrical connections between each of the one or more electronic components having length and width substantially similar to the length and width of electrical connections within the one or more electronic components. Advantageously, in some embodiments, enabling formation of an increased number of electrical connections between each of the one or more electronic components, which, in turn, enables downsizing, fast signal/data transfer and, in turn, reducing the power consumption.

Advantageously, the disclosed multi-chip module configuration allows enhancing heat dissipation therefrom, thereby enhancing thermal performance, reducing the power consumption, and improving the yield and performance thereof. In some embodiments, positioning powerful dies substantially directly on the heat sink substantially/virtually removes the heat dissipation restrictions.

It may be understood by one skilled in the art that during die manufacturing, there is a probability of defects and malfunctions formation (including fatal defects). Further, the probability of defects increases exponentially with an increase in the die area. Advantageously, in some embodiments, in the disclosed multi-chip module and methods for manufacturing thereof, the probability of such defects is significantly reduced (since bare and small dies are implemented therein and are electrically interconnected), resulting in high yield.

It may also be further understood by one skilled in the art that one of the major losses in microcircuit yield originate from ultra-dense lower metal layers (e.g., a solder layer) and due to the aforementioned manufacturing defects (e.g., in particular, e.g., in large transistors (in terms of area)). In some embodiments, the disclosed herein multi-chip module may be advantageously devoid of large transistors (e.g., by placing small and/or individual and/or bare dies/transistors). In some embodiments, the disclosed herein multi-chip module may be advantageously devoid of the ultra-dense lower metal layers, thereby increasing reliability and yield thereof.

Advantageously, in some embodiments, the disclosed multi-chip module and methods for manufacturing thereof may be devoid of packaging. Advantageously, in some embodiments, the disclosed multi-chip module and methods for manufacturing thereof may be devoid of printed circuit boards (PCBs) and hence of limitations thereof. As a result, in some embodiments, the input/output ports of the one or more electronic components (e.g., chips) of the multi-chip module may be positioned at a distance significantly lower compared to the distance therebetween in a typical PCB (e.g., distance of about 500 um in a typical PCB design). According to some embodiments, the distance between the input/output ports of the one or more electronic components of the disclosed herein multi-chip module may be about 20 um or less, about 10 um or less, about 8 um or less, about 6 um or less, about 5 um or less, about 4 um or less, about 2.5 um or less, about 2.5-10 um, about 5-10 um, about 2.5-5 um. Each possibility is a separate embodiment. Thereby, in some embodiments, the disclosed multi-chip module may allow increasing the number of input/output ports by about 2500 times (e.g., without using a case as a space converter).

Advantageously, in some embodiments, the disclosed multi-chip module enables heterogeneous integration of the one or more electronic components, thereby allowing design and manufacture of a wide variety of systems. According to some embodiments, the disclosed multi-chip module enables combining different die types, generations, materials, and technologies. As a non-limiting example, Si, SiC, GaN, GaAs and InP transistors and/or diodes, resistors, capacitors, inductors, optical devices, RF and DC components, and the like, or any combination thereof, may be advantageously integrated into a single system/module.

According to some embodiments, an input/output ports pitch of the multi-chip module may be about 20 um or lower.

According to some embodiments, the one or more electrical components of the multi-chip module may include one or more of: bare die, chips, micromechanical systems (MEMS), memory interfaces, input/output devices, graphics processing unit, radio modem, passive components, processor, analog integrated circuits, RF integrated circuits, voltage regulator module, or any combination thereof. According to some embodiments, the passive components may include inductors and/or capacitors, and the like.

According to some embodiments, the insulating material of the coreless interposer may be made of or include one or more polymers.

According to some embodiments, spaces between the one or more electronic components may be filled with a molding material.

According to some embodiments, the molding material may be selected from polyimide, epoxy, benzocyclobutene (BCB) or any combination thereof.

According to some embodiments, the multi-chip module may further include a thermal interface material (TIM) configured for attaching the heat sink to the backside of the one or more components.

According to some embodiments, the thermal interface material (TIM) may have a thickness of less than about 50 nanometer.

According to some embodiments, the plurality of conducting lines/pads may be made of or include copper, silver, gold or other metals.

According to some embodiments, the multi-chip may be suitable for use in analogue, digital, RF and/or high-power circuits.

According to some embodiments, the multi-chip module may be a stand-alone system in a package (SiP) module.

According to some embodiments, a distance between the one or more electrical components may be about 100 um or less.

According to some embodiments, there is provided a method for manufacturing a multi-chip module, the method including positioning one or more electronic components on an inert carrier, wherein the carrier comprises a coating capable of controlled detachment therefrom; coating/covering the one or more electronic components with a molding material, such that the one or more electronic components are covered by the molding material and wherein a space between the one or more electronic components is filled with the molding material, thereby obtaining a molded multi-component structure; grinding the multi-component structure until a backside of all of the one or more electronic components in the multi-component structure is exposed; attaching a heat sink to the exposed backside, such that a front side of the molded multi-component structure faces the carrier and the backside of the multi-component structure faces the heat sink; and building up a coreless interposer on the front side of the multi-component structure.

According to some embodiments, the method further includes detaching the inert carrier from the multi-component structure.

According to some embodiments, the disclosed herein method for manufacturing a multi-chip module is technically simple, highly reliable, and suited for cost-effective mass-production.

According to some embodiments, the method may be devoid of drilling.

According to some embodiments, the interposer of the disclosed method may include a plurality of layers, wherein each of the plurality of layers includes a plurality of conducting lines/pads and one or more gaps between the plurality of conducting lines/pads, wherein the one or more gaps are filled with an insulating material.

According to some embodiments, the method may further include applying the coating on the carrier prior to the positioning, wherein the coating is configured to allow penetration of pillars attached to the one or more electronic components, while preventing penetration of the one or more electronic components.

According to some embodiments, the method may further include partially curing the coating prior to the positioning of the one or more electronic components.

According to some embodiments, the method may further include curing the coating after the positioning of the one or more electronic components.

According to some embodiments, the method may further include planarizing the front side of the multi-component structure after the detaching from the carrier and prior to the generation of the coreless interposer.

Certain embodiments of the present disclosure may include some, all, or none of the above advantages. One or more other technical advantages may be readily apparent to those skilled in the art from the figures, descriptions, and claims included herein. Moreover, while specific advantages have been enumerated above, various embodiments may include all, some, or none of the enumerated advantages.

Unless otherwise defined, all technical and scientific terms used herein have the same meaning as commonly understood by one of ordinary skill in the art to which this disclosure pertains. In case of conflict, the patent specification, including definitions, governs. As used herein, the indefinite articles “a” and “an” mean “at least one” or “one or more” unless the context clearly dictates otherwise.

### BRIEF DESCRIPTION OF THE FIGURES

Some embodiments of the disclosure are described herein with reference to the accompanying figures. The description, together with the figures, makes apparent to a person having ordinary skill in the art how some embodiments may be practiced. The figures are for the purpose of illustrative description and no attempt is made to show structural details of an embodiment in more detail than is necessary for a fundamental understanding of the disclosure. For the sake of clarity, some objects depicted in the figures are not drawn to scale. Moreover, two different objects in the same figure may be drawn to different scales. In particular, the scale of some objects may be greatly exaggerated as compared to other objects in the same figure.

In the figures:

FIG. 1 schematically depicts a cross-sectional side view of a multi-chip module (MCM), according to some embodiments;

FIG. 2 schematically depicts an example of a method for manufacturing an MCM, according to some embodiments;

FIG. 3A schematically depicts a side view of a coreless interposer of an MCM, according to some embodiments;

FIG. 3B schematically depicts a top view of the coreless interposer of FIG. 3A, according to some embodiments;

FIG. 3C schematically depicts a top view of each of plurality of layers of the coreless interposer of FIG. 3A, according to some embodiments;

FIG. 4 shows a flow chart of a method for manufacturing a coreless interposer, according to some embodiments;

FIG. 5 schematically illustrates an example of an additive manufacturing method for forming electrically conducting regions of a coreless interposer, according to some embodiments; and

FIG. 6 schematically illustrates an example of a semi-additive manufacturing method forming electrically conducting regions of a coreless interposer, according to some embodiments.

### DETAILED DESCRIPTION

The principles, uses, and implementations of the teachings herein may be better understood with reference to the accompanying description and figures. Upon perusal of the description and figures present herein, one skilled in the art will be able to implement the teachings herein without undue effort or experimentation.

In the description and claims of the application, the words “include” and “have”, and forms thereof, are not limited to members in a list with which the words may be associated.

As used herein, the term “about” may be used to specify a value of a quantity or parameter (e.g. the length of an element) to within a continuous range of values in the neighborhood of (and including) a given (stated) value. According to some embodiments, “about” may specify the value of a parameter to be between 80% and 120% of the given value. For example, the statement “the length of the element is equal to about 1 m” is equivalent to the statement “the length of the element is between 0.8 m and 1.2 m”. According to some embodiments, “about” may specify the value of a parameter to be between 90% and 110% of the given value. According to some embodiments, “about” may specify the value of a parameter to be between 95% and 105% of the given value.

As used herein, according to some embodiments, the terms “substantially” and “about” may be interchangeable.

As used herein, according to some embodiments, the term “one or more electronic components” may refer to any circuit and/or electronic components mounted, attached, fixed or otherwise incorporated into a multi-chip module. According to some embodiments, the one or more electronic components may include, among others, one or more of: a chip, semiconductor die, semiconductor device, micromechanical systems (MEMS), integrated circuit (e.g., application-specific integrated circuit), memory interfaces, input/output devices, graphics processing unit, microprocessor, microcontroller, a logic chip (e.g., analog-to-digital converter), radio modem, passive components, or any component thereof, and any combination thereof. Each possibility is a separate embodiment. According to some embodiments, the one or more electronic components may include, among others, one or more of: a silicon die, a silicon carbide die (e.g., a SiC metal-oxide-silicon field-effect transistor (MOSFET)), a gallium nitride die (e.g., a bare GaN high electron mobility transistor (HEMT), a gallium arsenide (GaAs) die, and the like, or any combination thereof. Each possibility is a separate embodiment. According to some embodiments, the one or more electronic components may refer to bare components (such as, but not limited to, bare dies).

As used herein, according to some embodiments, the terms “electrically conducting regions”, “electrical connections”, “contact pads”, “electrically conducting lines” and “electrically conducting pads” may be used interchangeably and may refer to any electrically conducting portions, such as conducting portions of a coreless interposer. According to some embodiments, the conductive lines may be made of or include metals, such as, but not limited to, copper (Cu), gold (Au), silver (Ag), nickel (Ni), tin (Sn), titanium (Ti) and the like, or any alloys thereof. Each possibility is a separate embodiment. According to some embodiments, the conducting regions are configured to electrically interconnect, rout and/or re-rout integrated circuit devices and/or components thereof, such as, but not limited to, microprocessors, memory devices, chipsets, graphics devices, one or more dies, and the like, or any combination thereof. According to some embodiments, the conductive lines may, among others, refer to electrical traces. Additionally, or alternatively, in some embodiments, the conductive lines may form a conducting pathway (vertical electrical connections) between plurality of layers of the coreless interposer, as further elaborated elsewhere herein. According to some embodiments, the conductive lines may form various types of vias, such as, but not limited to, through-vias, tented vias, blind vias, buried vias, stacked vias, and the like, or any combination thereof. Each possibility is a separate embodiment. According to some embodiments, in contrast conventionally formed vias, the disclosed herein vias are formed devoid of drilling. According to some embodiments, in contrast to conventionally formed vias, the disclosed herein vias may be formed devoid of etching.

According to some embodiments, there is provided herein a multi-chip model and methods for manufacturing thereof. According to some embodiments, the multi-chip model comprises an open/exposed/bare backside including a heat sink, one or more electronic components, and a front side including an interposer, wherein the one or more electronic components are positioned between the interposer and the heat sink, and wherein the front side is configured for electrical communication with other/external components or devices.

Advantageously, the disclosed multi-chip module configuration allows enhancing heat dissipation therefrom, thereby enhancing thermal performance, reducing the power consumption, and improving the yield and performance of an electronic device.

According to some embodiments, the electronic device may refer to, among others, a smartphone, a tablet, a laptop, a television, a wearable electronic device (e.g., smartwatch), a robot, a video game machine, a network system, a digital camera, space avionics, an RF module, a high-power communication device, and the like, or any combination thereof.

According to some embodiments, the disclosed herein method for manufacturing a multi-chip module is technically simple, cost-effective, highly reliable, and readily suited for cost-effective mass-production of the multi-chip module, as further described in greater detail elsewhere herein.

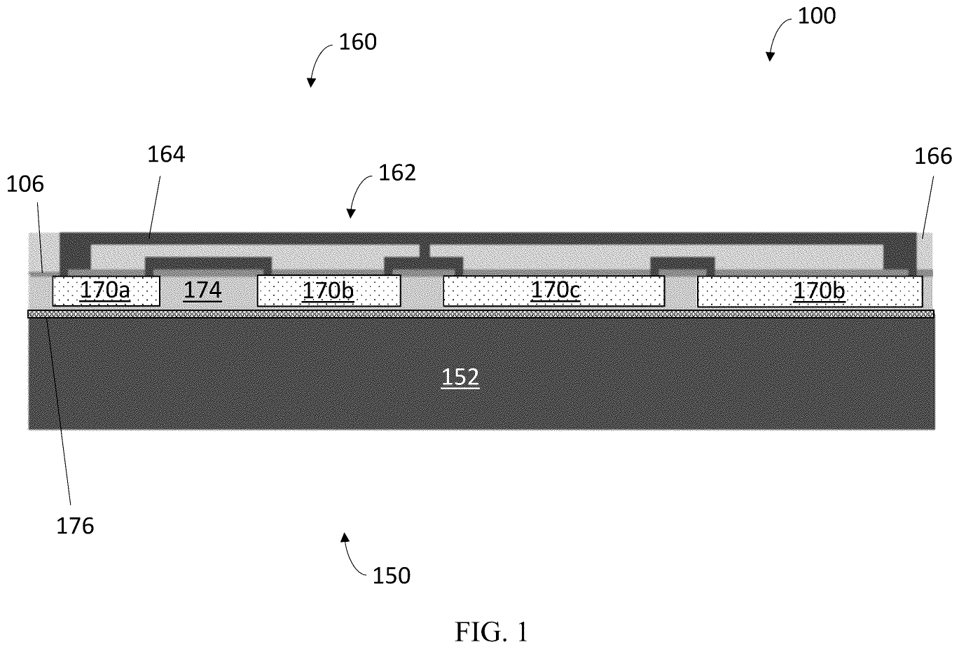

Reference is made to FIG. 1, which schematically depicts a cross-sectional side view of a multi-chip module (MCM) 100, according to some embodiments. Advantageously, in some embodiments, MCM 100 enables minimization of an electronic device, improves the performance of the electronic device due to an increased speed of data transmission thereto and therefrom, and due to the enhanced heat dissipation from the electronic device. Advantageously, in some embodiments, MCM 100 reduces the power required for operating thereof.

According to some embodiments, MCM 100 may be a stand-alone system in a package (SiP) module.

According to some embodiments, MCM 100 is suitable for use in analogue, digital, RF and/or high power circuits.

According to some embodiments, MCM 100 includes a back side 150 exposing a heat sink 152, a front side 160 having an interposer 162, and one or more electronic components 170a-d positioned therebetween.

According to some embodiments, heat sink 152 of back side 150 is configured for direct heat dissipating (i.e., thermal energy dissipating) from MCM 100 into environment surrounding MCM 100. Scenarios for which it might be particularly beneficial to utilize heat sink 152 and enhance the heat dissipation may include an MCM (e.g., MCM 100) used for high-power applications, wherein a significant amount of thermal energy is generated by the MCM.

According to some embodiments, heat sink 152 may be made of or include SiC, AIN, diamond, Cu, and the like, or any combination thereof. According to some embodiments, heat sink 152 may include a fluid-cooled sink/plate (e.g., a water-cooled plate).

According to some embodiments, heat sink 152 may be attached to MCM 100 by an adhesive (e.g., a permanent adhesive film/layer). According to some embodiments, heat sink 152 may be attached to MCM 100 by a die attach film. According to some embodiments, heat sink 152 may be attached to MCM 100 by a thermal interface material (TIM) 176. According to some embodiments, the thickness of TIM 176 is selected to facilitate the heat dissipation (for example, by phonon scattering properties thereof). According to some embodiments, the thickness of TIM 176 may be about 50 nm or less. According to some embodiments, the thickness of TIM 176 may be about 40 nm or less. According to some embodiments, the thickness of TIM 176 may be about 35 nm or less. According to some embodiments, the thickness of TIM 176 may be about 30 nm or less. According to some embodiments, the thickness of TIM 176 may be about 25 nm or less. According to some embodiments, the thickness of TIM 176 may be about 20 nm or less. According to some embodiments, the thickness of TIM 176 may be about 15 nm or less. According to some embodiments, the thickness of TIM 176 may be about 10 nm or less. Each possibility is a separate embodiment. According to some embodiments, MCM 100 includes front side 160 configured for electrical communication with external electrical components. According to some embodiments, interposer 162 may be defined/formed/generated on front side 160. Alternatively, in some embodiments, interposer 162 may be attached to front side 160 of MCM 100. According to some embodiments, input/output ports of interposer 162 are configured for electrical communication with the external electrical components.

According to some embodiments, interposer 162 may be a coreless (substrate-less) interposer, as described in greater detail elsewhere herein. Alternatively, in some embodiments, interposer 162 may include a substrate (not shown), such as a glass, Si, organic, or any other type of a substrate. Each possibility is a separate embodiment.

According to some embodiments, interposer 162 includes a plurality of layers. According to some embodiments, each of the plurality of layers includes a plurality of electrically conducting lines/pads 164 and one or more gaps between the plurality of electrically conducting lines/pads 164. According to some embodiments, the one or more gaps are filled with an insulating material 166, as described in greater detail elsewhere herein.

According to some embodiments, plurality of conducting lines/pads 164 may be made of or include copper (Cu), silver (Ag), gold (Au), titanium (Ti), nickel (Ni), tin (Sn) or other metals, or alloys thereof. According to some embodiments, insulating material 166 of interposer 162 may include one or more polymers. According to some embodiments, insulating material 166 may be made of or include polyimide.

According to some embodiments, defining interposer 162 on front side 160 enables formation of a fan-out package on front side 160, wherein back side 150 is bare/open/exposed, thereby advantageously facilitating the heat dissipation and minimizing warpage of MCM 100.

According to some embodiments, MCM 100 includes one or more electronic components 170a-d. In some embodiments, MCM 100 may include one electronic component (e.g., one chip). Put differently, in some embodiments, MCM 100 may refer to a single-chip module.

According to some embodiments, spaces between the one or more electronic components 170a-d are filled with a molding material 174. According to some embodiments, molding material 174 may be selected from polyimide, epoxy, benzocyclobutene (BCB) or any combination thereof.

According to some embodiments, back side of one or more electronic components 170a-d may be assembled/positioned on a coating 106, as described in greater detail elsewhere herein.

According to some embodiments, an input/output ports pitch of MCM 100 may be about 20 um or lower. According to some embodiments, an input/output ports pitch of MCM 100 may be about 15 um or lower. According to some embodiments, an input/output ports pitch of MCM 100 may be about 10 um or lower. According to some embodiments, an input/output ports pitch of MCM 100 may be about 8 um or lower. According to some embodiments, an input/output ports pitch of MCM 100 may be about 5 um or lower. Each possibility is a separate embodiment.

As a non-limiting example, the input/output ports pitch of MCM 100 may be about 10 um or lower, while the conventional input/output ports pitch of chips on a printed circuit board is about 500 um. Consequently, MCM 100 allows manufacturing MCM 100 having the same area as the printed circuit board while increasing the input/output ports by 2500. Hence, advantageously, minimizing the electronic device, increasing data transmission speed, reducing the amount of the generated heat, facilitating heat dissipation and, hence, obtaining an electronic device with a higher yield.

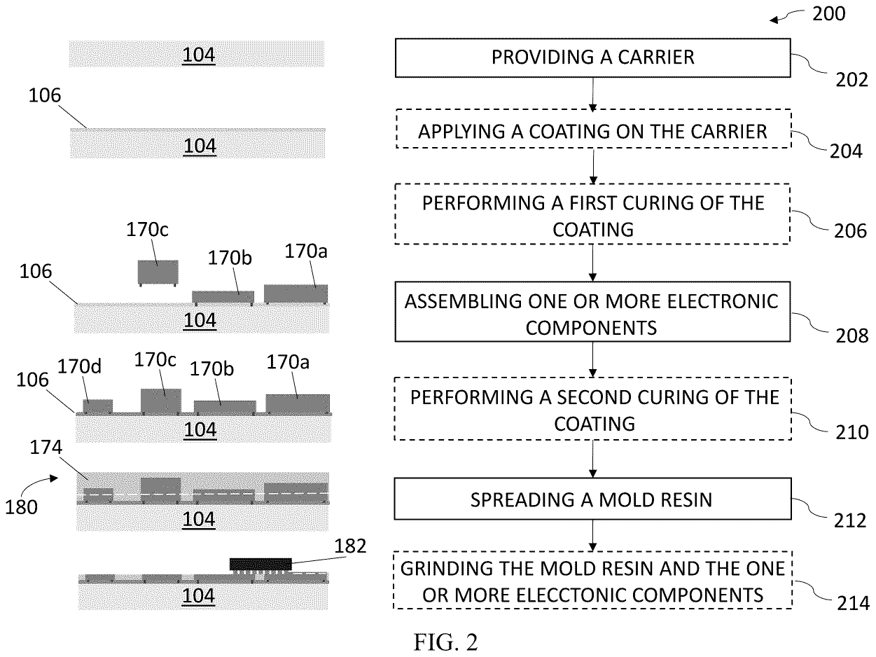

Reference is made to FIG. 2 which shows a flowchart 200 of a method for manufacturing an MCM, and schematically illustrates steps of the method, according to some embodiments.

According to some embodiments, FIG. 2 schematically illustrates an example of a method for manufacturing an MCM, such as MCM 100 of FIG. 1.

According to some embodiments, at step 202, the method may include providing a carrier substrate 104. According to some embodiments, carrier substrate 104 may be provided in an uncoated form (i.e., an uncoated carrier substrate). Alternatively, in some embodiments, carrier substrate 104 may be provided with a coating 106.

According to some embodiments, at step 202, carrier substrate 104 may be inert. According to some embodiments, carrier substrate 104 may be made of or include, among others, glass (e.g., coated glass, uncoated glass, and the like). As a non-limiting example, carrier substrate 104 may be made of or include a glass coated with a polyimide coating (e.g., coating 106). According to some embodiments, carrier substrate 104 may be made of or include, among others, glass, ceramic materials, polymers, stainless steels, and the like, or any combination thereof. Each possibility is a separate embodiment. According to some embodiments, carrier substrate 104 may be made of or include SiC. According to some embodiments, carrier substrate 104 may be made of or include AIN. According to some embodiments, carrier substrate 104 may be made of or include polyimide. Each possibility is a separate embodiment.

According to some embodiments, carrier substrate 104 may be rigid (e.g., having Shore hardness of about 85 D-96 D). According to some embodiments, carrier substrate 104 may be flexible. As a non-limiting example, Shore hardness of carrier substrate 104 may be, among others, in a range of about 50 D-70 D. According to some embodiments, carrier substrate 104 may be semi-rigid (e.g., of a combined hardness of the rigid and the flexible substrates). Each possibility is a separate embodiment.

According to some embodiments, carrier substrate 104 may be a temporary substrate (i.e., may be removed during manufacturing).

According to some embodiments, at step 204, the method may optionally include applying coating 106 on carrier substrate 104. According to some embodiments, at step 204, the method may optionally include applying coating 106 on carrier substrate 104 prior to positioning one or more electronic components 170a-d, as described in a greater detail elsewhere herein. According to some embodiments, coating 106 is capable of controlled detachment from carrier substrate 104.

According to some embodiments, coating 106 may be made of or include one or more polymers. According to some embodiments, coating 106 is configured to allow penetration of pillars of one or more electronic components 170a-d therein, while preventing penetration of the one or more electronic components 170a-d.

According to some embodiments, coating 106 may be made of or include one or more epoxy resins. According to some embodiments, coating 106 may be made of or include polyimide.

According to some embodiments, at step 206, the method may optionally include performing a first curing of coating 106 prior to positioning one or more electronic components 170a-d. According to some embodiments, the first curing may be a partial curing. According to some embodiments, the first curing may be performed until coating 106 is approximately 10%-80% cured. As a non-limiting example, the first curing may be performed until coating 106 is approximately 10%, 20%, 30%, 40%, 50%, 60%, 70%, 80% cured. Each possibly is a separate embodiment.

According some embodiments, at step 208, the method may include positioning/assembling the one or more electronic components 170a-d on carrier substrate 104. According to some embodiments, one or more electronic components 170a-d may include, among others, 1, 2, 3, 4, 5, 6, 7, 8, 9, 10, 15, 20 or more electronic components. Each possibility is a separate embodiment.

According to some embodiments, each of the one or more electronic components 170a-d may differ in dimensions (i.e., height, width, length, or any combination thereof). According to some embodiments, each of the one or more electronic components 170a-d may have different power consumption, different potentials, and the like.

According to some embodiments, one or more electronic components 170a-d are bare, e.g., a bare semiconductor die, bare chip, and the like, or any combination thereof.

According to some embodiments, one or more electronic components 170a-d are positioned/assembled in a face-down orientation. According to some embodiments, one or more electronic components 170a-d may be positioned/assembled in one layer (i.e., one floor/plane).

According to some embodiments, a distance between the one or more electronic components 170 a-d may be about 100 um or less. According to some embodiments, a distance between the one or more electronic components 170 a-d may be about 150 um or less. According to some embodiments, a distance between the one or more electronic components 170 a-d may be in a range of about 50-200 um. According to some embodiments, a distance between the one or more electronic components 170a-d may be in a range of about 50 -150 um. According to some embodiments, a distance between the one or more electronic components 170 a-d may be about 90 um or less. Each possibility is a separate embodiment. As a non-limiting example, the method may include positioning one or more electronic components 170a-d to obtain a chip-to-chip distance of less than about 100 um. Hence, in some embodiments, the method advantageously enables reducing the time for signal transferring, saving space and reducing energy consumption.

According to some embodiments, at step 210, the method may include performing a second curing of coating 106 (i.e., performing curing after the positioning of the one or more electronic components). According to some embodiments, the second curing is configured to facilitate fixing a position of each of the one or more electronic components 170a-d.

According to some embodiments, at step 212, the method may include coating/covering one or more electronic components 170a-d with a molding material 174. According to some embodiments, coating/covering with molding material 174 may be performed such that the one or more electronic components 170a-d are covered by the molding material 174 and wherein a space between the one or more electronic components 170a-d is filled with molding material 174, thereby obtaining a multi-component structure 180.

According to some embodiments, molding material 174 may be made of or include, among others, one or more polymers. According to some embodiments, molding material 174 may be made of or include polyimide, epoxy, benzocyclobutene (BCB) or any combination thereof.

According to some embodiments, at step 214, the method may include grinding the multi-component structure 180 until a backside of all of one or more electronic components 170a-d in multi-component structure 180 is exposed. According to some embodiments, grinding multi-component structure 180 may include grinding molding material 174 and the one or more electronic components 170a-d.

According to some embodiments, grinding multi-component structure 180 may be performed, among others, by using a schematically depicted grinding tool/machine 182. According to some embodiments, at step 216, the method may optionally include applying a thermal interface material (TIM) 176 configured for attaching a heat sink 152 to the backside of the one or more electronic components 170a-d. According to some embodiments, TIM 176 may be a permanent adhesive.

According to some embodiments, the thickness of TIM 176 may be about 50 nm or less. According to some embodiments, the thickness of TIM 176 may be about 40 nm or less. According to some embodiments, the thickness of TIM 176 may be about 35 nm or less. According to some embodiments, the thickness of TIM 176 may be about 30 nm or less. According to some embodiments, the thickness of TIM 176 may be about 25 nm or less. According to some embodiments, the thickness of TIM 176 may be about 20 nm or less. According to some embodiments, the thickness of TIM 176 may be about 15 nm or less. According to some embodiments, the thickness of TIM 176 may be about 10 nm or less. Each possibility is a separate embodiment.

According to some embodiments, at step 218, the method may include attaching heat sink 152 to the exposed backside, such that a front side of the multi-component structure 180 faces carrier 104 and the backside of the multi-component structure 180 faces heat sink 152.

According to some embodiments, at step 220, the method may optionally include detaching carrier 104 from multi-component structure 180.

According to some embodiments, at step 222, the method may include planarizing the front side surface/upper layers of the multi-component structure 180. According to some embodiments, step 222 may be performed after the detaching from the carrier 104 (i.e., after step 220) and prior to the generation of a coreless interposer 162.

According to some embodiments, a surface planner tool/machine may be used for performing the planarizing of a layer having electrically insulating (e.g., polymer) regions (e.g., molding material 174) and electrically conducting regions. According to some embodiments, the electrically conducting regions may include pillars or balls 172 of one or more electronic components 170a-d. According to some embodiments, and as depicted in FIG. 2B, the pillar or balls 172 may have a non-uniform height. According to some embodiments, the surface planer tool/machine may use a diamond bit for grinding/planarizing to facilitate the planarizing ductile materials (such as, but not limited to, Cu, Au, and the like), resins (such as, but not limited to, polyimide), or any combination thereof. According to some embodiments, planarizing the front side surface/upper layers of multi-component structure 180 may increase the reliability of electrical interconnection of the multi-component structure 180 with other devices or components.

According to some embodiments, the planarizing allows obtaining a total thickness variation (TTV) of multi-component structure 180 lower than about 1 um. According to some embodiments, the planarizing allows obtaining a total thickness variation (TTV) of multi-component structure 180 lower than about 0.8 um. According to some embodiments, the planarizing allows obtaining a total thickness variation (TTV) of multi-component structure 180 lower than about 0.5 um, without leading to formation of cracks or other defects by the planarization procedure.

According to some embodiments, at step 224, the method may include building up/forming an interposer 162 on the front side of the multi-component structure, thereby obtaining a multi-chip module (MCM) 100.

According to some embodiments, the method for manufacturing MCM 100 is devoid of drilling (e.g., laser drilling, or any other type of drilling). Consequently, in some embodiments, the resolution of MCM 100 is not limited by the aspect ratio (i.e., height to diameter) of the vertical electrical connections. As a result, in some embodiments, enabling formation of vias and input/output ports with high density, complex routing pattens, and substantially unlimited via height is facilitated. According to some embodiments, the method for manufacturing MCM 100 is devoid of drilling, advantageously, minimizing/preventing the risk for formation of cracks and warpage and other defects/deformations, and increasing the reliability of MCM 100 performance.

According to some embodiments, interposer 162 may be a coreless interposer, as elaborated in greater detail elsewhere herein. According to some embodiments, interposer 162 may be a 3D interposer.

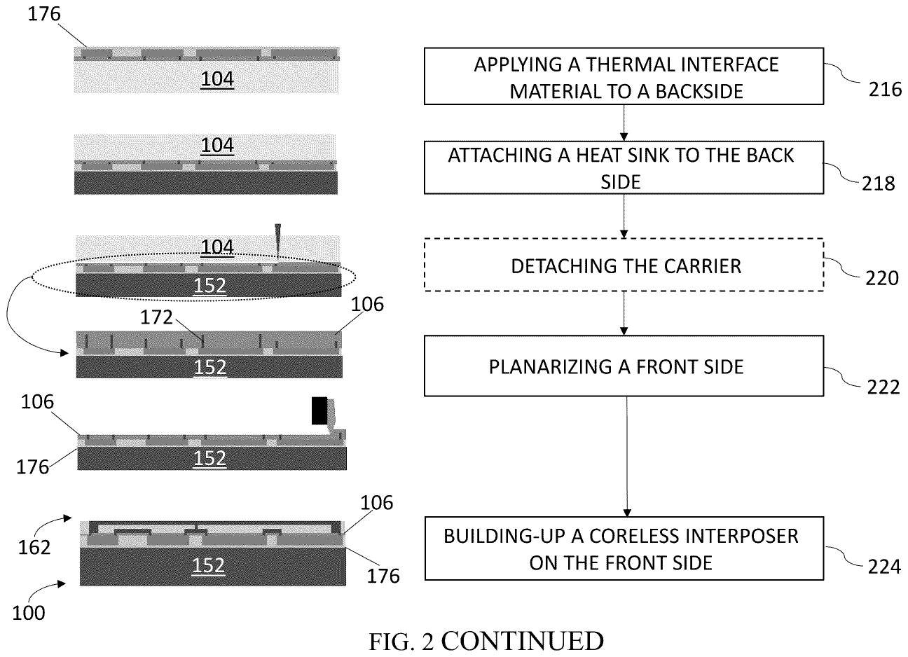

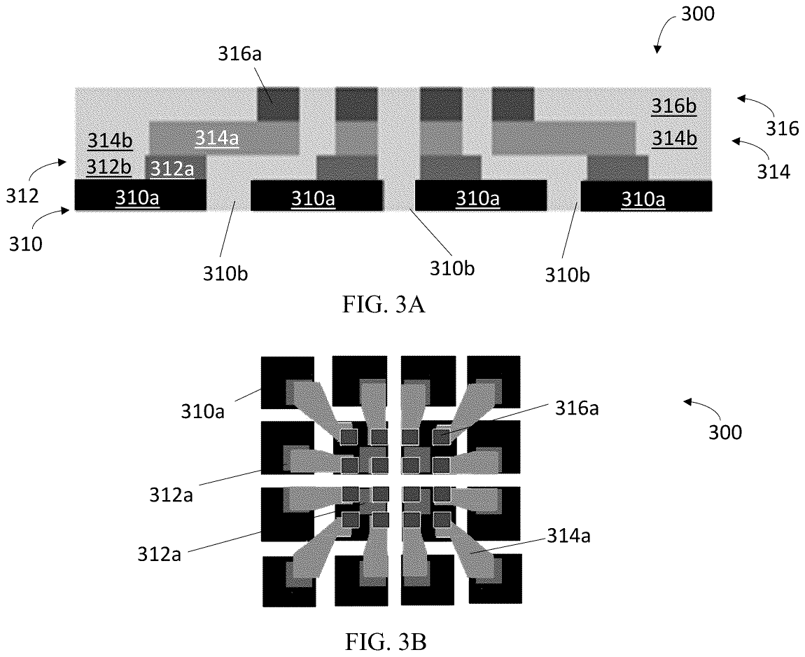

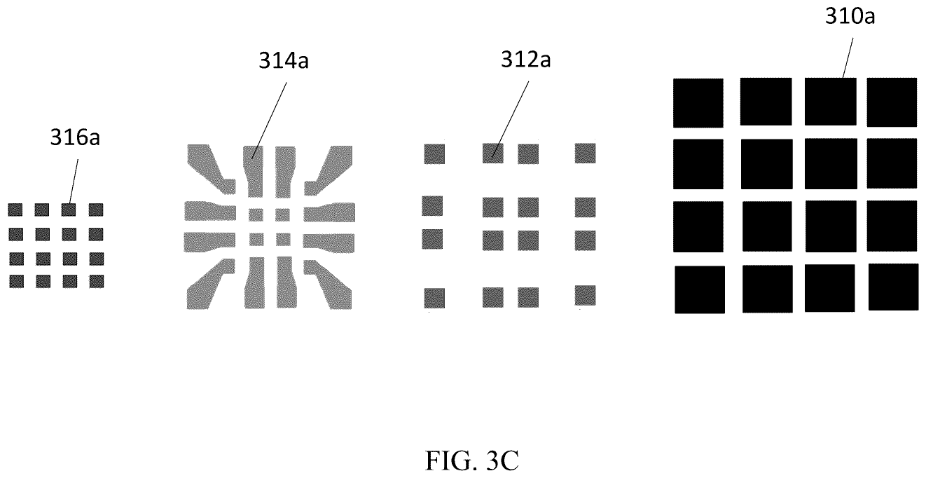

Reference is now made to FIG. 3A, which schematically depicts a side view of a coreless interposer 300 of an MCM, to FIG. 3B which schematically illustrates a top view thereof, and to FIG. 3C, which schematically illustrates a top view of a plurality of layers of coreless interposer 300, according to some embodiments.

According to some embodiments, coreless interposer 300 may be similar or identical to interposer 162 of FIG. 1 in MCM 100.

According to some embodiments, coreless interposer 300 is configured to allow electrical interconnection, routing and rerouting between one or more electronic components of the MCM and external components/devices.

According to some embodiments, coreless interposer 300 is configured to electrically interconnect various types bare electronic components, such as but not limited to, bare dies. According to some embodiments, coreless interposer 300 is configured to electrically interconnect microprocessors (e.g., single-core and/or multi-core processors), microcontrollers, memory chips (such as volatile memory, a non-volatile memory, and the like), logic chips, integrated circuits, any passive and/or active components or device, or any other electrical components, semiconductor devices, and the like, or any combination thereof.

Advantageously, in some embodiments, a line/space resolution of coreless interposer 300 may be at least about 5/5 um. In some embodiments, a line/space resolution of coreless interposer 300 may be at least about 4/4 um. In some embodiments, a line/space resolution of coreless interposer 300 may be at least about 3/3 um. Each possibility is a separate embodiment.

According to some embodiments, the contact pitch (spatial separation between nearest vias) of coreless interposer 300 may be below about 5 um. According to some embodiments, contact pitch of coreless interposer 300 may be below about 4 um. According to some embodiments, the contact pitch of coreless interposer 300 may be below about 3 um. According to some embodiments, the contact pitch of coreless interposer 300 may be below about 2.5 um. Each possibility is a separate embodiment. According to some embodiments, coreless interposer 300 has a substrate-less structure. According to some embodiments, electrically conductive lines of coreless interposer 300 are formed devoid of drilling, etching, or otherwise penetrating thereof, thereby minimizing/preventing cracking or otherwise deforming thereof, while allowing increasing the density and the resolution of the electrically conductive lines (and of vias formed by the electrically conductive lines, as further elaborated elsewhere herein).

According to some embodiments, coreless interposer 300 is a three-dimensional (3D) interposer. According to some embodiments, coreless interposer 300 may include a plurality of high-density electrically conductive lines defined therein. According to some embodiments, coreless interposer 300 may include a plurality of ultra-thin and high-density vertical electrical interconnections formed therein. Advantageously, in some embodiments, coreless interposer 300 enables miniaturizing electronic devices while improving the interconnection, thereby improving the performance and decreasing the power consumption of the electronic devices.

According to some embodiments, coreless interposer 300 may have an ultra-thin structure e.g., a thickness of about 50 um or lower. According to some embodiments, coreless interposer 300 may have an ultra-thin structure e.g., a thickness of about 40 um or lower. According to some embodiments, coreless interposer 300 may have an ultra-thin structure e.g., having a thickness of about 30 um or lower. According to some embodiments, coreless interposer 300 may have an ultra-thin structure e.g., having a thickness of about 20 um or lower. According to some embodiments, coreless interposer 300 may have an ultra-thin structure e.g., having a thickness of about 10 um or lower. According to some embodiments, coreless interposer 300 may have an ultra-thin structure e.g., having a thickness in a range of about 5 to about 500 um. Each possibility is a separate embodiment. In some embodiments, coreless interposer 300 may have any desired thickness (i.e., substantially unlimited height).

According to some embodiments, coreless interposer 300 may have a plurality of layers (e.g. 2, 3, 4, 5, 6, 7, 8, 9, 10 or more layers). Each possibility is a separate embodiment. According to some embodiments, thickness of each of the plurality of layers may be substantially the same. In some embodiments, thickness of each of the plurality of layers may be different.

According to some embodiments, each of the plurality of layers is stacked above a previous (bottom) layer. According to some embodiments, each of the plurality of layers include electrically conducting regions, and an electrically insulating regions (i.e., electrically insulating material) filling gaps between the electrically conducting regions. According to some embodiments, each of the insulating regions is positioned between each of the electrically conducting regions, thereby preventing (horizontal) current flow (i.e., shorts) between each of the plurality of conducting regions at a specific layer of the plurality of layers. Put differently, the plurality of layers is substantially vertically stacked, forming vertical electrical connections between insulating regions, thereby allowing vertical current flow through the plurality of layers according to a predefined pattern/path.

Advantageously, in some embodiments, the structure of coreless interposer 300 enables on-the-fly formation of vertical electrical connections between the electrically insulating material. According to some embodiments, the vertical electrical connections of each of the plurality of layers may be formed simultaneously. Advantageously, in some embodiments, the vertical electrical connections are formed devoid of drilling. Advantageously, in some embodiments, the vertical electrical connections are formed devoid of etching (e.g., chemical etching). Advantageously, the vertical electrical connections may be formed in any desired pattern and/or height, to facilitate routing the electrical signal.

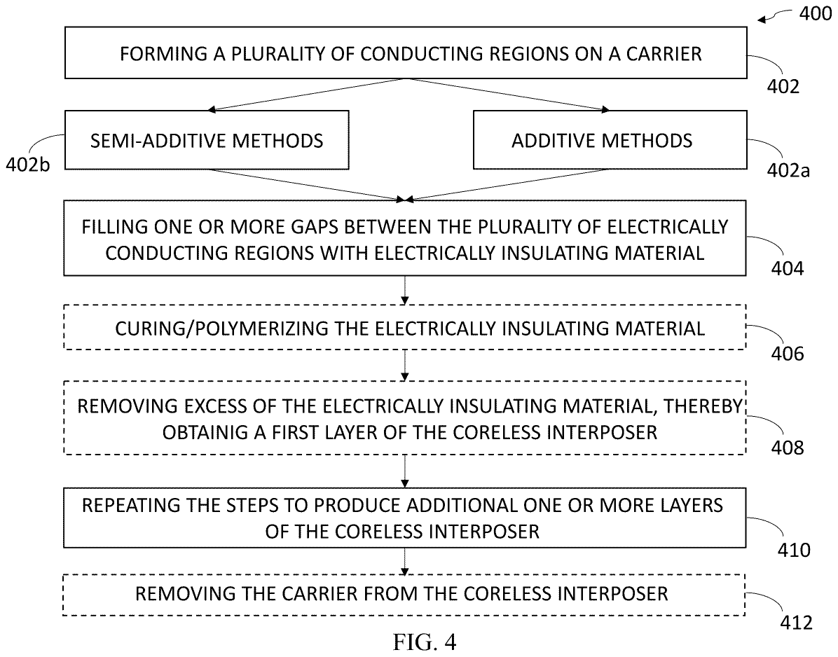

According to some embodiments, and as depicted in FIGS. 3A-C, the plurality of layers of coreless interposer 300 may include four layers. According to some embodiments, and as depicted in FIG. 3A, a first layer 310 of the plurality of layers includes a plurality of electrically conducting regions 310a and a plurality of electrically insulating regions 310b. According to some embodiments, and as depicted in FIG. 3A, each of a second layer 312, a third layer 314 and a fourth layer 316 of the plurality of layers includes a plurality of electrically conducting regions 312a, 314a and 316a and a plurality of electrically insulating regions 312b, 314b and 316b, respectively. It may be understood that the number of the plurality of layers of coreless interposer 300 may vary and include substantially any required number thereof. According to some embodiments, the number of the plurality of layers may include, among others, 2, 3, 4, 5, 6, 7, 8, 9, 10, 15, 20, 25, 30 or more layers. Each possibility is a separate embodiment. According to some embodiments, there is substantially no upper limit for the number of the plurality of layers, as described in greater detail in FIG. 4.

According to some embodiments, and as depicted in FIGS. 3A-C, plurality of electrically conducting regions 310a of first layer 310 may include a first plurality of contact pads configured to electrically interconnect to an external component/device (e.g., configured to interconnect an MCM to an external component/device). According to some embodiments, dimensions of each of the first plurality of contact pads may be about 100 um×100 um. According to some embodiments, dimensions of each of the first plurality of contact pads may be in the range of about 100-500 um×100-500 um. According to some embodiments, dimensions of each of the first plurality of contact pads may be in the range of about 50-500 um×50-500 um. Each possibility is a separate embodiment. According to some embodiments, the plurality of electrically conducting regions 312a of second layer 312 may be configured for facilitating/forming a desired pattern and/or size of vertical electrical connections. According to some embodiments, plurality of electrically conducting material regions 314a of third layer 314 may optionally include and/or serve as a redistribution layer (RDL) configured for rerouting the vertical electrical connections to desired locations. According to some embodiments, the plurality of electrically conducting regions 316a of fourth layer 316 may include a second plurality of contact pads, wherein the second plurality of contact pads is configured to interconnect coreless interposer 300 to one or more electronic components of the MCM. According to some embodiments, the dimensions of each of the second plurality of contact pads may be about 10×10 um or lower. According to some embodiments, dimensions of each of second plurality of contact pads may be about 8×8 um or lower. According to some embodiments, dimensions of each of second plurality of contact pads may be about 6×6 um or lower. According to some embodiments, dimensions of each of second plurality of contact pads may be about 5x 5 um or lower. According to some embodiments, dimensions of each of second plurality of contact pads may be about 4×4 um or lower. According to some embodiments, dimensions of each of second plurality of contact pads may be about 3×3 um or lower. According to some embodiments, dimensions of each of second plurality of contact pads may be about 2.5×2.5 um or lower. Each possibility is a separate embodiment.

According to some embodiments, lines and/or contact pads of the electrically conducting material regions may have a thickness of about 5-7 um or 3-6 um. According to some embodiments, the lines and/or pads may have a thickness of less than about 5 um.

According to some embodiments, electrically conducting regions 310a/312a/314a/316a may include or be in a form of contact pads. According to some embodiments, a form/shape of electrically conducting regions 310a/312a/314a/316a may include or be in a form of a circle, square, oblong, rectangle, rounded rectangle, chamfered rectangle, octagon, donut, n-sided polygon, and the like (when viewed from above), or any combination thereof. According to some embodiments, electrically conducting regions 310a/312a/314a/316a may include or be in a form of electrical lines.

According to some embodiments, vertical electrical connections formed by electrically conducting regions 310a/312a/314a/316a may be in a form of or include, among others, through-vias, tented vias, blind vias, buried vias, stacked vias, and the like, or any combination thereof. Each possibility is a separate embodiment.

Reference is made to FIG. 4, which is a flow chart 400 of a method for manufacturing a coreless interposer of an MCM, according to some embodiments.

According to some embodiments, at step 402, the method may include forming a plurality of electrically conducting regions. According to some embodiments, plurality of electrically conducting regions may include or be in the form of conductive lines. According to some embodiments, the plurality of electrically conducting regions may include or be in the form of contact pads. According to some embodiment, the plurality of electrically conducting regions may be formed according to a predefined pattern.

According to some embodiments, the plurality of electrically conducting regions may be made of or include metals. According to some embodiments, the plurality of electrically conducting regions may include copper (Cu), gold (Au), silver (Ag), tin (Sn), titanium (Ti), nickel (Ni), and the like, or any alloys thereof. Each possibility is a separate embodiment. According to some embodiments, each of the plurality of layers of the coreless interposer may be made of or include different materials (e.g., different metals). According to some embodiments, each of the plurality of layers of the coreless interposer may be made of or include the same materials (e.g., made of or include the same metal in each of the plurality of layers).

According to some embodiments, at step 402, the method may include forming the plurality of electrically conducting regions on a temporary carrier substrate. According to some embodiments, the temporary carrier substrate may be made of an inert material, such as, but not limited to glass, silicon, ceramics, stainless steel, SiC, AIN, polyimide, polyimide on glass and the like. According to some embodiments, the temporary carrier substrate may be rigid, semi-rigid or flexible. Each possibility is a separate embodiment.

According to some embodiments, the temporary carrier substrate may be uncoated. According to some embodiments, the carrier substrate may include a coating.

It may be understood by skilled in the art that, in some embodiments, the coreless interposer of FIG. 1-2 may be manufactured without using the temporary carrier substrate (i.e., manufactured directly on multi-component structure 180). Alternatively, in some embodiments, a coreless interposer may be manufactured separately/independently (i.e., on the temporary carrier substate) and then attached to multi-component structure 180.

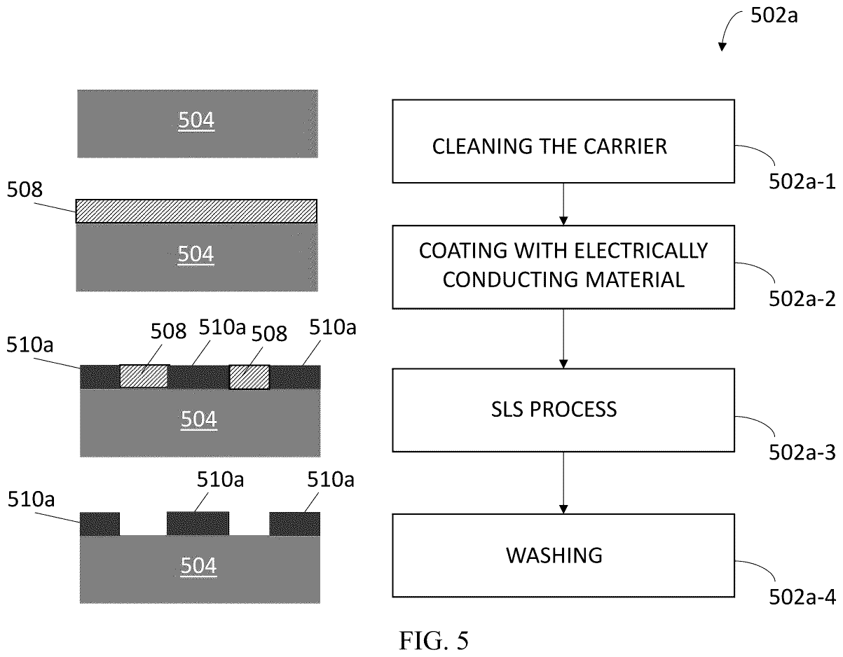

According to some embodiments, the plurality of electrically conducting regions may be formed by implementing an additive manufacturing method (step 402a), such as but not limited to, selective laser sintering, as elaborated in FIG. 5.

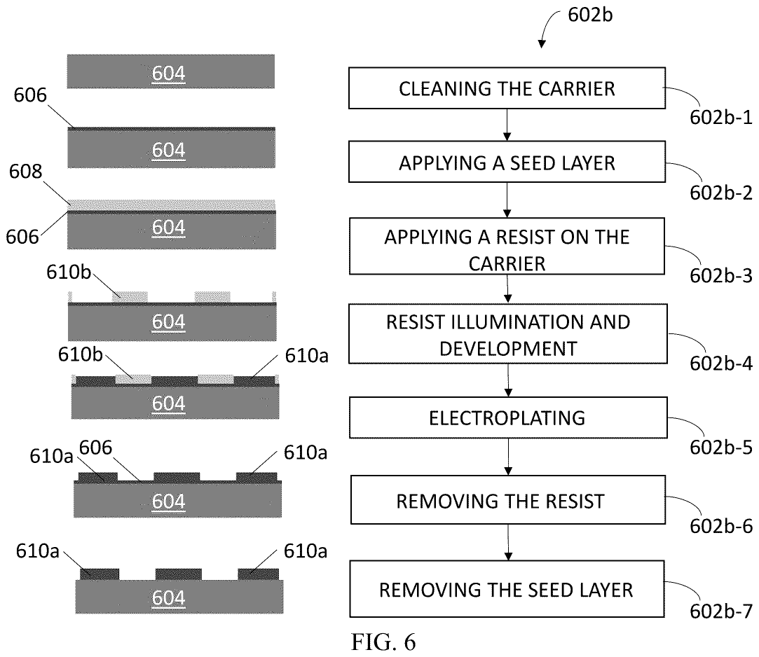

According to some embodiments, the plurality of electrically conducting regions may be formed by implementing a semi-additive manufacturing method (step 402b), such as but as but not limited to, photolithography, as further elaborated in FIG. 6.

According to some embodiments, at step 404, the method may include filling one or more gaps between the plurality of electrically conducting regions with electrically insulating material. According to some embodiments, the filling may include pouring/spreading the electrically insulating material over the plurality of electrically conducting regions and the one or more gaps therebetween.

According to some embodiments, the electrically insulating material may include dielectric materials. According to some embodiments, the electrically insulating material may include one or more polymers. According to some embodiments, the electrically insulating material may be made of or include polyimide. According to some embodiments, the electrically insulating material may be photosensitive. As a non-limiting example, the electrically insulating material may be made of or include photo definable epoxy. According to some embodiments, the electrically insulating material may be photo-insensitive. According to some embodiments, the electrically insulating material may include thickness to diameter ratio of at least about 5:1. According to some embodiments, the thickness of the electrically insulating material layer be in the range of about 3-30 um. According to some embodiments, the electrically insulating material has a coefficient of thermal expansion (CTE) of about 15-20 ppm/° C.

According to some embodiments, the CTE of the electrically conducting regions may substantially match the CTE of the electrically insulating material, thereby facilitating the thermal management and heat dissipation generated by an MCM away therefrom. It may be understood by skilled in the art that insufficient heat transfer results in performance degradation of the electronic device or components thereof. Furthermore, thermal expansion mismatch may lead to an increased mechanical stress, which, in turn, may also lead to performance degradation.

According to some embodiments, each of a plurality of layers of the coreless interposer may be made of or include different electrically insulating materials. According to some embodiments, each of the plurality of layers of the coreless interposer may be made of or include same electrically insulating material.

According to some embodiments, at step 406, the method may optionally include thermally treating, curing and/or polymerizing the electrically insulating material filling the one or more gaps between the plurality of electrically conducting regions.

According to some embodiments, at step 408, the method may include removing/scraping excess of the electrically insulating material, thereby obtaining a first layer of the plurality of layers of the coreless interposer.

According to some embodiments, removing/scraping off the excess of the electrically insulating material may include planarizing using a surface planer device/machine, such that a substantially flat surface of the first layer (and/or of each of additional one or more layers) of the coreless interposer is formed. According to some embodiments, the excess of the electrically insulating material may be removed until a portion of the electrically conducting regions (e.g., surface or top layer of the electrically conducting region) is exposed.

According to some embodiments, at step 410, the method may include repeating the abovementioned steps to produce an additional one or more layers of the coreless interposer. Put differently, the abovementioned steps may be repeated until the required number of the plurality of layers is obtained (e.g., until the required height/depth of vertical electrical connections is achieved).

According to some embodiments, the repeating may include aligning the electrically conductive regions of a previous/bottom layer of the plurality of layers with the additional layer of the plurality of layers of the coreless interposer. According to some embodiments, the aligning may be performed according to fiducials/landmarks of the previous/bottom layer. According to some embodiments, alignment between the electrically conductive regions of each of the plurality of layers may be about 1 um or lower. According to some embodiments, alignment between the electrically conductive regions of each of the plurality of layers may be about 0.5 um or lower. Each possibility is a separate embodiment. In some embodiments, the method disclosed herein allows manufacturing coreless interposers having mismatch loss of less than about 10% or less than about 5%. According to some embodiments, the method may optionally include a step 412 of removing the temporary carrier from the interconnecting structure.

According to some embodiments, the method may optionally include performing electrical measurements to test/verify at least a portion of the plurality of layers during and/or after manufacturing of the coreless interposer (step not shown).

According to some embodiments, the method provides an “on-the-fly” formation of vertical electrical connections between the electrically insulating material.

In some embodiments, the disclosed herein method is devoid of any drilling steps. In some embodiments, the method is devoid of mechanical drilling and laser drilling. Advantageously, the disclosed method is therefore not limited to a height to diameter aspect ratio of the via, as opposed to methods including drilling of the via which are prone to cracking of the interposer or parts thereof. Put differently, in some embodiments, the aspect ratio may be substantially infinite.

Advantageously, due to the absence of height to diameter aspect ratio limitations, in some embodiments, there are substantially no upper limit of the number of the plurality of layers stacked above each other, thereby allowing formation of vertical electrical connections (e.g., vias) between the electrically insulating material with substantially unlimited height/depth.

According to some embodiments, the predefined pattern of each of the plurality of layers may be different. According to some embodiments, complex and high-density patterns may be obtained, regardless of the number of the plurality of layers of the coreless interposer. Advantageously, in some embodiments, the disclosed herein methods combine additive manufacturing techniques for producing the coreless interposer interconnecting structure, such that the interposer is produced either by semi-additive or by additive (e.g., fully additive) methods. Thereby, in some embodiments, allowing obtaining a wide range of patterns (e.g., interconnecting schemes) and vias architectures, and hence achieving the required signal routing, signal integrity, and power delivery, while facilitating thermal management therethrough. In some embodiments, complex patterns of the vertical electrical connections may be achieved substantially without reducing or limiting the resolution (i.e., the density of the electrically conducting regions) of the coreless interposer. According to some embodiments, a line/space resolution of the interconnecting structure may be at least about 5/5 um.

In some embodiments, a coreless interposer and an MCM manufactured according to the disclosed herein method may be compatible with military standard testing of 1000 cycles from-45° C. to +145° C. In some embodiments, a coreless interposer and an MCM manufactured according to the disclosed herein method may be compatible with Joint Electron Device Engineering Council (JEDEC) standards, including testing of 1000 cycles from −25° C. to +125° C.

In some embodiments, the method disclosed herein allows manufacturing coreless interposers having mismatch loss of less than about 10% or less than about 5%. In some embodiments, the method disclosed herein allows manufacturing coreless interposers having conducting material total thickness variation (TTV) of less than about 1 um or less than about 0.5 um. In some embodiments, the method disclosed herein allows manufacturing coreless interposers having interlayer contact resistivity lower than about 1×10⁻⁶ ohm/cm².

Reference is made to FIG. 5, which schematically illustrates an example of an additive manufacturing method 502a for forming the electrically conducting regions (i.e., in step 402a in FIG. 4), according to some embodiments. According to some embodiments, the additive manufacturing method may include, among others, selective laser sintering (SLS) methods, such as but not limited to, direct SLS, direct metal laser sintering (DMLS), selective laser melting (SLM), metal lines 3D printing, electron beam melting (EBM), or any other additive manufacturing methods. According to some embodiments, the additive manufacturing method may include any type of directed energy deposition methods, powder-based fusion additive manufacturing methods, and the like, or any combination thereof. According to some embodiments, the additive manufacturing method may include micro-metal additive manufacturing (MMAM) methods.

According to some embodiments, at step 502a-1, the additive manufacturing method may include cleaning a carrier 504. According to some embodiments, carrier 504 may be a temporary carrier. Alternatively, in some embodiments, the carrier may be a non-temporary carrier.

According to some embodiments, cleaning carrier 504 may include performing plasma surface treatment. According to some embodiments, the plasma surface treatment may be performed by an atmospheric plasma. According to some embodiments, cleaning carrier 504 may include chemical etching (i.e., wet or dry etching) of the surface of carrier 504. According to some embodiments, cleaning carrier 504 may include dry etching of the surface of carrier 504. According to some embodiments, cleaning carrier 504 may include ultrasonic cleaning. According to some embodiments, cleaning carrier 504 may include ozone treatment of the surface of the carrier. According to some embodiments, cleaning carrier 504 may include any combination of the abovementioned cleaning methods, or any other surface treatment/cleaning.

According to some embodiments, at step 502a-2, the additive manufacturing method may include spreading/coating the surface of carrier 504 with an ink coating 508.

According to some embodiments, ink coating 508 may include a structural powder (i.e., a high-melting-point powder, such as metal or alloy), and a binder/solvent (i.e., a powder having a lower melting point than the structural powder). According to some embodiments, ink coating 508 may be made of or include a mixture of two or more powders. According to some embodiments ink coating 508 may include a mixture of conducting materials (e.g., a mixture of metals). According to some embodiments, ink coating 508 may include copper (Cu), gold (Au), silver (Ag), titanium (Ti), nickel (Ni), tin (Sn) in coatings, and the like, or any combination thereof. Each possibility is a separate embodiment. As a non-limiting example, ink coating 508 may be a copper ink coating. According to some embodiments, the binders/solvents of the ink coating may include, among others, water, ethylene glycol, diethylene glycol monomethyl ether, and the like. Each possibility is a separate embodiment. It may be understood by one of skill in the art that different binders and/or solvents produce a metal ink with different viscosities, thereby affecting filling abilities/properties thereof.

According to some embodiments, the coating of carrier 304 with in coating 508 may be performed by, among others, an ink spay coater, a slot-die coater, an ultrasonic spin-spay coater and the like, or any combination thereof. According to some embodiments, coating carrier 504 may include doctor blade coating, to facilitate formation of well-defined coating thickness.

According to some embodiments, step 502a-2 may include drying the ink coating 508. According to some embodiments, the drying may be performed, among others, by a blower, an oven, or the like.

According to some embodiments, at step 502a-3, the additive manufacturing may include performing selective laser sintering to form electrically conductive regions 510a according to a predefined pattern. According to some embodiments, a direct laser writer may be used for performing the selective laser sintering. According to some embodiments, step 502 a-3 may include 3D printing, electron beam melting, or any other additive manufacturing method.

According to some embodiments, at step 502a-4, the additive manufacturing method may include washing or otherwise removing the non-sintered material (e.g., the non-sintered copper ink of ink coating 508), thereby obtaining a pattern of the electrically conducting regions 510a. According to some embodiments, the pattern may include electrically conducting lines having a required width, length, and distance therebetween, as essentially disclosed herein.

According to some embodiments, additive manufacturing method 502a does not include any step of subtraction of material.

Reference is made to FIG. 6, which schematically illustrates an example of a semi-additive manufacturing method 602b for obtaining the electrically conducting regions (i.e., of step 402b in FIG. 4), according to some embodiments.

According to some embodiments, semi-additive method 602b may be based on or include lithography manufacturing methods. According to some embodiments, the lithography methods may include, among others, maskless lithography methods. According to some embodiments, lithography may include, among others, X-ray, electron-beam and/or optical lithography (i.e., photolithography), and the like. Each possibility is a separate embodiment. According to some embodiments, lithography may include, among others, nanolithography, plasmonic-assisted lithography, laser interference lithography, nanosphere lithography, and the like. Each possibility is a separate embodiment.

According to some embodiments, semi-additive method 602b may include photolithography.

According to some embodiments, at step 602b-1, the semi-additive method may include providing a carrier substrate 604. According to some embodiments, carrier 604 may be a temporary carrier. According to some embodiments, step 602b-1 may include cleaning carrier 604. According to some embodiments, the carrier cleaning may include performing plasma surface treatment. According to some embodiments, the carrier cleaning may include chemical etching (i.e., wet etching) of the surface of carrier 604. According to some embodiments, the carrier cleaning may include dry etching of the surface of carrier 504. According to some embodiments, the carrier cleaning may include ultrasonic cleaning, ozone treatment, plasma treatment and the like, or any combination thereof, of the surface of the carrier. Each possibility is a separate embodiment. According to some embodiments, the carrier cleaning may include any combination of the abovementioned cleaning methods, or any other suitable surface treatment/cleaning.

According to some embodiments, at step 602b-2, the semi-additive method may include forming a seed layer 606 on carrier 604. According to some embodiments, seed layer 606 may be made of or include one or more metals. According to some embodiments, seed layer 606 may include TiW and Cu.

According to some embodiments, seed layer 606 may be formed by metallization processes. According to some embodiments, seed layer 506 may be formed by physical vapor deposition (PVD) methods, such as sputtering or thermal evaporation. According to some embodiments, seed layer 606 may be formed by chemical vapor deposition (CVD) methods, such as atomic layer deposition (ALD). Each possibility is a separate embodiment.

According to some embodiments, at step 602b-3, the semi-additive method may include applying of a radiation-sensitive compound on the seed layer 606. According to some embodiments, the radiation-sensitive compound may include a resist, such as a positive resist (i.e., the formed pattern in the positive resist is the same as the pattern on the mask) or a negative resist (i.e., the formed pattern is reverse of the mask pattern). According to some embodiments, the resist may include a photoresist 608.

According to some embodiments, carrier 604 may be positioned on a vacuum spindle while applying the photoresist. According to some embodiments, carrier 604 may be then rotated (e.g., for about 15 seconds, about 30 seconds, about 60 seconds, and the like), to facilitate obtaining a uniform coating of photoresist 606. According to some embodiments, the coated carrier 604 may optionally undergo a pre-patterning thermal treatment (e.g., baking), to remove solvent from photoresist 608 and/or to enhance adhesion of photoresist 608 to seed layer 606.

According to some embodiments, at step 602b-4, the semi-additive method may include photoresist illumination and development (pattern transferring). According to some embodiments, step 602b-4 may be performed in a clean room illuminated with yellow light. According to some embodiments, step 602b-4 may include applying radiation, such as ultraviolet radiation, to transfer the desired pattern to photoresist 608, forming a photoresist pattern 610b.

According to some embodiments, following completing transferring the pattern, remnants of photoresist 608 may be removed from the unpattern portions, thereby exposing photoresist pattern 610b formed on seed layer 606. According to some embodiments, the remnants of photoresist 608 may be removed from the unpattern portions by washing, sonicating, etching, and/or rinsing in a solution, plasma oxidation, and the like, or any combination thereof.

According to some embodiments, a second thermal treatment (e.g., post baking) may be optionally performed after developing the pattern on carrier 604. According to some embodiments, carrier 604 and the developed photoresist pattern 610b may be dried in an ambient environment.

According to some embodiments, at step 602b-5, the semi-additive method may include filling one or more gaps between photoresist pattern 610b with an electrically conducting material, such that a plurality of electrically conducting regions 610a is formed. According to some embodiments, plurality of electrically conducting regions 610a may be formed, among others, by electroplating. As a non-limiting example, step 604b-5 may include copper electroplating.

According to some embodiments, at step 602b-6, the semi-additive method may include removing photoresist pattern 610b. According to some embodiments, photoresist pattern 610b may be removed by wet chemistry techniques. According to some embodiments, AZ 100 remover may be used for removing photoresist pattern 610b. According to some embodiments, AZ 920 remover may be used for removing photoresist pattern 610b. According to some embodiments, 1-methyl-2-pyrrolidone (NMP) remover may be used for removing photoresist pattern 610b. According to some embodiments, dimethyl sulfoxide (DMSO) may be used (e.g., by ultrasonic cleaning) for removing photoresist pattern 610b.

According to some embodiments, at step 602b-7, the semi-additive method may include removing seed layer 606 remnants between plurality of electrically conducting regions 610a to prevent horizontal current flow between each of plurality of electrically conducting regions 610a through each of the plurality of layers of the coreless interposer, thereby allowing vertical current flow (i.e., between each of the plurality of layers of the coreless interposer).

According to some embodiments, the remnants of seed layer 606 may be removed by etching or any other suitable removal technique.

It is appreciated that certain features of the disclosure, which are, for clarity, described in the context of separate embodiments, may also be provided in combination in a single embodiment. Conversely, various features of the disclosure, which are, for brevity, described in the context of a single embodiment, may also be provided separately or in any suitable sub-combination or as suitable in any other described embodiment of the disclosure. No feature described in the context of an embodiment is to be considered an essential feature of that embodiment, unless explicitly specified as such.

Although stages of methods, according to some embodiments, may be described in a specific sequence, the methods of the disclosure may include some or all of the described stages carried out in a different order. In particular, it is to be understood that the order of stages and sub-stages of any of the described methods may be reordered unless the context clearly dictates otherwise, for example, when a latter stage requires as input an output of a former stage or when a latter stage requires a product of a former stage. A method of the disclosure may include a few of the stages described or all of the stages described. No particular stage in a disclosed method is to be considered an essential stage of that method, unless explicitly specified as such.

Although the disclosure is described in conjunction with specific embodiments thereof, it is evident that numerous alternatives, modifications, and variations that are apparent to those skilled in the art may exist. Accordingly, the disclosure embraces all such alternatives, modifications, and variations that fall within the scope of the appended claims. It is to be understood that the disclosure is not necessarily limited in its application to the details of construction and the arrangement of the components and/or methods set forth herein. Other embodiments may be practiced, and an embodiment may be carried out in various ways.

The phraseology and terminology employed herein are for descriptive purpose and should not be regarded as limiting. Citation or identification of any reference in this application shall not be construed as an admission that such reference is available as prior art to the disclosure. Section headings are used herein to ease understanding of the specification and should not be construed as necessarily limiting.

1. A multi-chip module comprising:
an open/exposed/bare backside comprising a heat sink, the heat sink configured for heat dissipation from the multi-chip module;
one or more electronic components; and
a front side comprising a coreless interposer comprising:
a plurality of layers, wherein each of the plurality of layers comprises a plurality of conducting lines/pads; and
one or more gaps between the plurality of conducting lines/pads, wherein the one or more gaps are filled with an insulating material; and
wherein the one or more electronic components are positioned between the coreless interposer and the heat sink; and
wherein the front side is configured for electrical communication with external electrical components.

2. The multi-chip of claim 1, wherein an input/output ports pitch of the multi-chip module is about 20 um or lower.

3. The multi-chip of claim 1, wherein the one or more electrical components comprise one or more of: bare die, chips, micromechanical systems (MEMS), memory interfaces, input/output devices, a graphics processing unit, a radio modem, passive components, processors, analog integrated circuits, RF integrated circuits, a voltage regulator module, or any combination thereof.

4. The multi-chip of claim 1, wherein the insulating material of the coreless interposer is made of or comprises one or more polymers.

5. The multi-chip module of claim 1, wherein spaces between the one or more electronic components are filled with a molding material.

6. The multi-chip module of claim 5, wherein the molding material is selected from polyimide, epoxy, benzocyclobutene (BCB) or any combination thereof.

7. The multi-chip of claim 1, further comprising a thermal interface material (TIM) configured for attaching the heat sink to the backside of the one or more components.

8. The multi-chip of claim 7, wherein the thermal interface material (TIM) has a thickness of less than about 50 nanometer.

9. The multi-chip module of claim 1, wherein the plurality of conducting lines/pads is made of or comprises copper, silver, gold or other metals.

10. The multi-chip module of claim 1, wherein the multi-chip is suitable for use in analogue, digital, RF and/or high-power circuits.

11. The multi-chip module of claim 1, wherein the multi-chip module is a stand-alone system in a package (SiP) module.

12. The multi-chip module of claim 1, wherein a distance between the one or more electrical components may be about 100 um or less.

13. A method for manufacturing a multi-chip module, the method comprising:
positioning one or more electronic components on an inert carrier, wherein the carrier comprises a coating capable of controlled detachment therefrom;
coating/covering the one or more electronic components with a molding material, such that the one or more electronic components are covered by the molding material and wherein a space between the one or more electronic components is filled with the molding material, thereby obtaining a molded multi-component structure;
grinding the multi-component structure until a backside of all of the one or more electronic components in the multi-component structure is exposed;
attaching a heat sink to the exposed backside, such that a front side of the molded multi-component structure faces the carrier and the backside of the multi-component structure faces the heat sink; and
building up a coreless interposer on the front side of the multi-component structure.

14. The method of claim 13, further comprising detaching the inert carrier from the multi-component structure.

15. The method of claim 13, wherein the method is devoid of drilling.

16. The method of claim 13, wherein the interposer comprises a plurality of layers, wherein each of the plurality of layers comprises a plurality of conducting lines/pads and one or more gaps between the plurality of conducting lines/pads, wherein the one or more gaps are filled with an insulating material.

17. The method of claim 13, further comprising applying the coating on the carrier prior to the positioning, wherein the coating is configured to allow penetration of pillars attached to the one or more electronic components, while preventing penetration of the one or more electronic components.

18. The method of claim 13, further comprising partially curing the coating prior to the positioning of the one or more electronic components.

19. The method of claim 13, further comprising curing the coating after the positioning of the one or more electronic components.

20. The method of claim 13, further comprising planarizing the front side of the multi-component structure after the detaching from the carrier and prior to the generation of the coreless interposer.
